(19) United States
(12) Patent Application Publication
(10) Pub. No.: US 2006/0125666 A1
(43) Pub. Date: Jun. 15, 2006

(54) Data modulation

(76) Inventor: Darwin M. Hanks, Ft. Collins, CO (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/012,438

(22) Filed: Dec. 14, 2004

Related U.S. Application Data
(60) Provisional application No. 60/635,710, filed on Dec. 12, 2004.

(51) Int. Cl. H03M 3/00

(52) U.S. Cl. 341/143

(57) ABSTRACT

A method for data modulation comprising identifying an N-bit block of data bits and modulating said block into an (N+1)-bit codeword.

### RELATED APPLICATION

The present invention claims priority to a provisional application, serial number unknown, of the same title and by the same inventor filed on Dec. 12, 2004.

### BACKGROUND

Numerous applications utilize digital data transmission for data communication, such as sending information via internet web sites or storing information on compact discs. Digital transmission systems or digital storage systems typically use a sequence of binary information, either delivered to a receiver across a transmission channel or stored to a medium (e.g., CDROM). Such a sequence of information is referred to as a data stream.

It is typically desirous to ensure that data streams do not contain long sequences comprising only “1” value bit or long sequences comprising only “0” value bits. Long sequences of a single value cause the direct current (DC) voltage level average within related circuitry to approach the positive or negative peaks of the system signal voltage range, which is typically undesirable in many applications. Additionally, it is often desirable to reserve certain data patterns (e.g., all “1” bits or all “0” bits) to identify certain conditions that will not appear in normal data. For example, it may be desired to identify a particular location on a CD (e.g., where valid data begins, ends, etc.) using a particular data pattern reserved as an “index” mark, often all “1” bits or all “zero” bits. Ensuring that normal data streams do not contain such patterns allows these patterns to be reserved, for example, for use as index marks.

Data modulation techniques have often been employed to avoid the presence of certain bit patterns, such as discussed above, in data streams. For example, Digital Video Disk (DVD) technology typically uses a modulation stream that converts 8 bits of data into 16 bit words, and by the insertion of the additional 8 bits, ensures that certain patterns are avoided. Other systems, such as compact disc (CD) systems, use similar modulation techniques.

While such techniques have allowed certain bit patterns to be avoided, further improvement is desired. Existing modulation schemes result in an inefficient use of data resources. For example, the DVD system referred to above generally requires the amount of data transmitted to be double the initial data amount in order to adequately represent the initial data while at the same time perform the functions desired to be achieved by the modulation, such as avoiding certain bit patterns and controlling the average DC voltage in related circuitry. This results in system efficiency that is lower than desired.

A need exists for a data modulation technique that will allow for the identification of index data and the control of the average DC voltage in related circuitry, while at the same time improving upon the efficiency of existing modulation techniques. This invention fulfills this need, among others.

### BRIEF DESCRIPTION OF THE DRAWINGS

For the purpose of illustrating the invention, there is shown in the drawings one exemplary implementation; however, it is understood that this invention is not limited to the precise arrangements and instrumentalities shown.

FIG. 1 is a flow chart illustrating the steps of an exemplary implementation of the present invention.

FIG. 2 is a table illustrating the codebook associated with an exemplary implementation of the present invention.

### DETAILED DESCRIPTION

Various types of systems utilize digital data transfer to communicate information. One exemplary system that employs digital data transfer is the LightScribe® Media Identification System (hereinafter “the LightScribe system”) produced by Hewlett-Packard (Palo Alto, Calif.). The exemplary embodiment of the invention described herein shall be described with reference to use on the LightScribe system; however, it is understood that embodiments of the invention could be used on other systems that use digital data transfer.

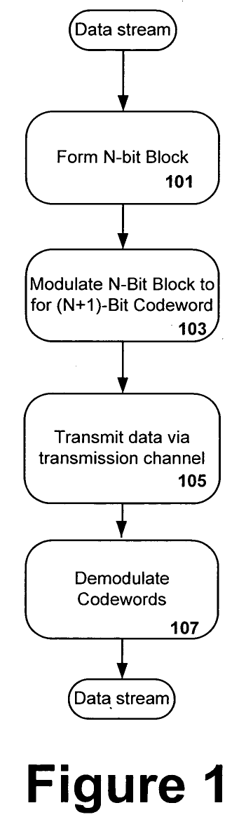

Initially, a data stream comprises a sequence of information in binary form. Referring to FIG. 1, the steps involved in an exemplary implementation of the present invention is shown. The initial data stream is partitioned into blocks (101) on N bits. In the exemplary implementation, the blocks comprise seven data bits (i.e., N=7). For example, the data can be partitioned into error control coding symbols of seven bits each.

Each N-bit block is modulated into an (N+1)-bit codeword (103). In the exemplary embodiment, the seven-bit blocks are modulated into eight-bit codewords. Using the modulation technique as described herein adds only a single bit to the data block, thus it requires a minimal amount of system resource overhead.

The modulated codeword may be transmit via a transmission channel (105), or alternatively read from a storage medium. In the exemplary embodiment, the transmission step involves the reading of the modulated codeword from an optical medium (e.g., CDROM), although various data transmission channels can be used. Upon receipt by a receiver, the modulated codeword is demodulated in accordance with the modulation technique to restore the original seven-bit codeword (107).

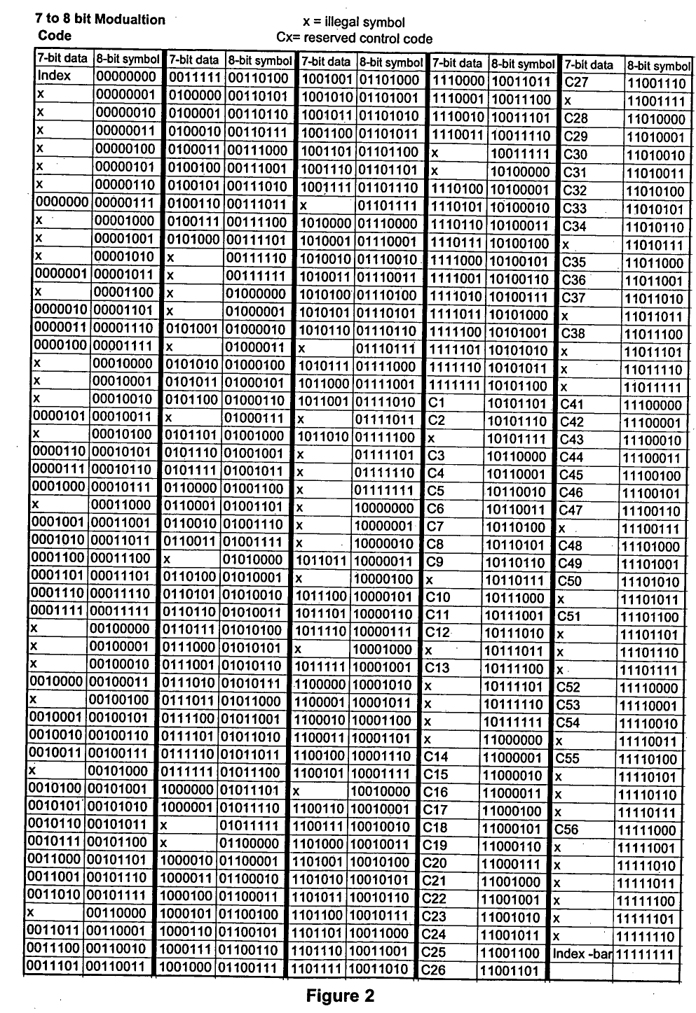

Referring to FIG. 2, a codebook detailing a modulation technique whereby N is equal to seven bits in accordance with an exemplary implementation of the present invention is shown. The illustrative modulation technique comprises assigning each seven-bit block to a valid eight-bit codeword. Only codewords that comply with a predetermined set of conditions are deemed to be valid. In the exemplary implementation, each valid code word contains no fewer than three “1” bits and no fewer than three “0” bits. Each seven-bit block is assigned in order to a valid codeword obtained from the codebook.

The table shown in FIG. 2 illustrates possible seven-bit blocks and the respective codewords to which they are assigned. Column 1 (“Data”) lists the possible unmodulated seven-bit blocks. Colunm 2 (“Symbol”) lists the corresponding codewords assigned to each possible seven-bit block. Codewords that contain fewer than three binary “1” bits of the eight possible bits are deemed to be invalid, and thus are skipped during the assignment process. Codewords that contain fewer than three binary “0” bits of the eight possible bits are deemed to be invalid, and thus these codewords are also skipped. Using these parameters, each seven-bit block is assigned to a valid codeword having a “3-to-5” bit condition, meaning that each valid codeword contains between three and five “1” bits and between three and five “0” bits. For example, referring to FIG. 2, the first block comprising “0000000” is assigned to the first valid codeword, which is “00000111.” The first seven codewords (00000000, 00000001, 00000010, 00000011, 00000100, 00000101, and 00000110) are skipped, as these codewords are deemed to be invalid for failing to meet the “3-to-5” condition. The next three eight-bit codewords are also skipped (00001000, 00001001, 00001010) for the same reason, with the next seven-bit block (0000001) being assigned to the next valid eight-bit codeword (00001011). This process is repeated until all possible seven-bit blocks have been assigned to a corresponding eight-bit codeword. In the exemplary embodiment, the codewords are assigned sequentially to the seven-bit blocks. For example, the first seven-bit block is “0000000” and is assigned to the first codeword “0000111”; the next seven-bit block is assigned to the next codeword in ascending numerical sequential order (i.e., “0000001” is assigned to “00000111”). However, alternative embodiments include assigning in other orders (e.g., descending order, randomly, etc.). As long as there is a one-to-one relationship between each seven-bit block and a corresponding valid codeword, the modulation technique will achieve the desired results.

After all possible seven-bit block combinations have been assigned, there are usually several valid eight-bit codewords remaining that have not been matched with a seven-bit block. As these remaining codewords are not required to modulate the seven-bit blocks, they are available to be used to in various applications for other functions (e.g., as control words, etc.).

The codewords in accordance with the modulation scheme illustrated in FIG. 2 provide several advantages over the existing modulation schemes currently employed in digital data application. The seven-to-eight scheme is more efficient than schemes currently used such as the 8 to 16 bit scheme employed currently in DVD systems. Only a single extra parity bit is added to the seven bit blocks. Additionally, by using the Seven-to-Eight modulation in accordance with an exemplary embodiment of the invention, data index marks containing all “1” bits or all “0” bits are prevented from occurring in the normal data stream. Furthermore, the Seven-to-Eight modulation in accordance with an exemplary embodiment of the invention ensures that the DC voltage average in related circuitry of the data will not normally be less than ⅜^{th} of the peak to peak amplitude of the system signal nor greater than ⅝^{th} of the peak to peak amplitude of the system signal as each modulated codeword will contain between three and five “1” bits.

A variety of modifications to the embodiments described will be apparent to those skilled in the art from the disclosure provided herein. Thus, the present invention may be embodied in other specific forms without departing from the spirit or essential attributes thereof and, accordingly, reference should be made to the appended claims, rather than to the foregoing specification, as indicating the scope of the invention.

1. A method for data modulation comprising:
identifying an N-bit block of data bits; and
modulating said block into an (N+1)-bit codeword.

2. The method as set forth in claim 1, wherein N is equal to seven.

3. The method as set forth in claim 2, wherein said seven-bit block is formed by partitioning a data stream into seven-bit segments.

4. The method as set forth in claim 2, wherein said seven-bit block comprises an error control coding symbol.

5. The method as set forth in claim 2, wherein said modulating step comprises:
determining if a codeword is valid, and
assigning said block to said codeword only if said codeword is valid.

6. The method as set forth in claim 5, wherein said codeword is determined to be valid if said codeword contains no fewer than three binary “1” bits and no fewer than three binary “0” bits.

7. The method as set forth in claim 5, wherein said assigning step comprises assigning a corresponding codeword to said seven-bit block in accordance with a codebook.

8. The method as set forth in claim 2, further comprising transmitting said codeword via a transmission channel.

9. The method as set forth in claim 8, wherein said transmitting is accomplished using a transmission signal with an average DC voltage level between ⅜^{th} and ⅝^{th} of the system signal peak to peak DC voltage level.

10. A method for generating a codebook for modulating data, the method comprising:
providing a list of potential data blocks having N data bits; and
providing a corresponding valid (N+1)-bit codeword for the listed data blocks.

11. The method as set forth in claim 10, wherein N is equal to seven.

12. The method as set forth in claim 10, wherein each of said corresponding (N+1)-bit codewords complies with a predetermined criteria.

13. The method as set forth in claim 12, wherein N is equal to seven and said predetermined criteria requires each codeword to have no fewer than three binary “1” bits sequential and no fewer than three binary “0” bits.

14. The method as set forth in claim 10 wherein all potential data blocks are listed sequentially.

15. The method as set forth in claim 14, using said codebook to modulate data; and wherein the using step is performed by a computing device.

16. A computer program product comprising a computer useable medium having program logic stored thereon, wherein said program logic comprises machine readable code executable by a computer in communication with a network, wherein said machine readable code comprises instructions for:
identifying an N-bit block of data bits; and
modulating said block into an (N+1)-bit codeword.

17. The computer program product as set forth in claim 16, wherein N is equal to seven.

18. The computer program product as set forth in claim 16, wherein said machine readable code further comprises instructions for:
transmitting said (N+1) bit codeword over a transmission channel.

19. The computer program product as set forth in claim 18, wherein said transmission channel comprises reading data from an optical medium.

20. A computer program product as set forth in claim 16, wherein said modulating is performed by assigning a corresponding codeword to said seven-bit block in accordance with a codebook.
